(19) United States
(12) Patent Application Publication
(10) Pub. No.: US 2012/0098562 A1
(43) Pub. Date: Apr. 26, 2012

(54) PROBE TIP COATING STRUCTURE FOR TEST PROBES

(75) Inventor: Po-Chao TAN, Zhonghe City (TW)

(73) Assignee: Brymen Technology Corporation

(21) Appl. No.: 12/909,035

(22) Filed: Oct. 21, 2010

(51) Int. Cl. G01R 1/067

(52) U.S. Cl. 324/755.01

(57) ABSTRACT

A probe tip coating structure for test probes includes a probe tip body and a coating element, and the probe tip body includes a rod and a probe head integrally formed a front end of the rod, and the external diameter of the rod is not greater than the external diameter of a base of the probe head, and the coating element is coated on the rod and forms a continuing section securely combined with the exterior of the rod, and a seat is coupled to an end of the continuing section and provided for assembling the test probe, such that the coating element is formed on the probe tip, and the external diameter of the coating element is close to that of the probe tip and the coating element can be securely combined with the probe tip without the risk of getting loosened or falling apart.

### FIELD OF THE INVENTION

The present invention relates to a test probe, in particular to a probe tip coating structure applied in a test probe of a multi-meter.

### BACKGROUND OF THE INVENTION

Multi-meter is a multifunctional electronic measuring instrument generally including the functions of an ammeter, a voltmeter, and an ohmmeter, and thus it is also known as a universal meter, a multi-purpose meter, or a multi-functional electric meter. Such instrument is usually operated together with one or more test probes for a connection and a measurement, and thus the instrument will not be restricted by the space and the using place, and it can be used extensively for measuring various types of electronic products.

In general, a test probe is inserted to measure various different electronic products without having limitations of space or the site of use.

A conventional test probe mainly includes a soft external sheath, a hard internal sheath, a conductive wire and a probe tip, and an end of conductive wire is passed into the hard internal sheath and electrically connected to an end of the probe tip, and another end of the probe tip is passed out and exposed from the hard internal sheath, and the soft external sheath is sheathed on the exterior of the hard internal sheath to form the test probe.

According to European specifications, a rod portion of a test probe must be coated by a layer of insulating material such as a thermoplastic film or sheathed by a sheath made of a soft insulating material. In the conventional way of coating the rod portion of the test probe with the thermoplastic film, the thermoplastic film may be loosened or fallen apart easily since the thermoplastic film cannot be combined securely with the probe tip. The other conventional way of adopting the sheath made of a soft insulating material imposes limitations on the application of the test probe, such as the incapability of examining a narrow plug hole of a socket, since the external diameter of the sheath is too large, and the size of the sheath cannot be reduced by a general manufacture.

In view of the aforementioned problems, the inventor of the present invention based on years of experience in the related industry to conduct extensive researches and experiments, and finally provided a feasible design to overcome the shortcomings of the conventional test probes.

### SUMMARY OF THE INVENTION

Therefore, the present invention is to provide a probe tip coating structure for test probes in compliance with standards of the European specifications, wherein an insulating coating element is formed on a probe tip, such that the external diameter of the coating element is close to the external diameter of the probe tip, and the coating element can be combined securely with the probe tip without having the risk of being loosened or falling apart easily.

The present invention discloses a probe tip coating structure for test probes, comprising a probe tip body and a coating element, and the probe tip body further comprises a rod and a probe head integrally formed at a front end of a rod, and the external diameter of the rod is not greater than the external diameter of a base of the probe head, and the coating element is coated onto the rod and forms a continuing section securely combined with the exterior of the rod, and a seat is coupled to an end of the continuing section and provided for assembling the test probe. The objective of the present invention can be achieved by forming the coating element on the probe tip body.

### BRIEF DESCRIPTION OF THE DRAWINGS

FIG. 1 is an exploded view of a first preferred embodiment of the present invention;

FIG. 2 is a perspective view of a first preferred embodiment of the present invention;

FIG. 3 is a perspective view of a probe tip coating structure installed onto a test probe in accordance with a first preferred embodiment of the present invention;

FIG. 4 is a partial cross-sectional view of a portion of FIG. 3;

FIG. 5 is a cross-sectional view of a second preferred embodiment of the present invention;

FIG. 6 is a cross-sectional view of a third preferred embodiment of the present invention;

FIG. 7 is a perspective view of a fourth preferred embodiment of the present invention;

FIG. 8 is a cross-sectional view of a fifth preferred embodiment of the present invention;

FIG. 9 is a partial cross-sectional view of a sixth preferred embodiment of the present invention;

FIG. 10 is a cross-sectional view of a seventh preferred embodiment of the present invention;

FIG. 11 is a cross-sectional view of an eighth preferred embodiment of the present invention; and

FIG. 12 is a partial cross-sectional view of a ninth preferred embodiment of the present invention.

### DESCRIPTION OF THE PREFERRED EMBODIMENTS

The technical characteristics and contents of the present invention will become apparent with the following detailed description accompanied with related drawings. The drawings are provided for the purpose of illustrating the present invention only, but not intended for limiting the scope of the invention.

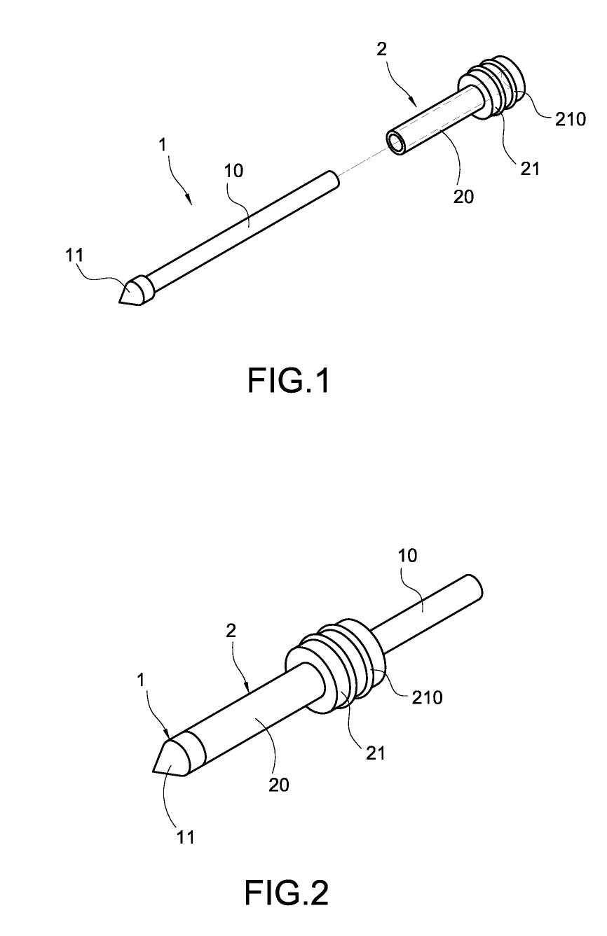

With reference to FIGS. 1 and 2 for an exploded view and a perspective view of a first preferred embodiment of the present invention respectively, a probe tip coating structure for test probes comprises a probe tip body 1 and a coating element 2.

The probe tip body 1 is made of an electrically conductive material, and includes a rod 10 and a probe head 11 integrally formed at a front end of the rod 10, and the probe head 11 is substantially cone-shaped, and the external diameter of the rod 10 is smaller than or equal to (not greater than) the external diameter of a base of the probe head 11, so that the coating element 2 can be securely combined with the rod 10 of the probe tip body 1, and the external diameter of the rod 10 can be less than 2.4 mm.

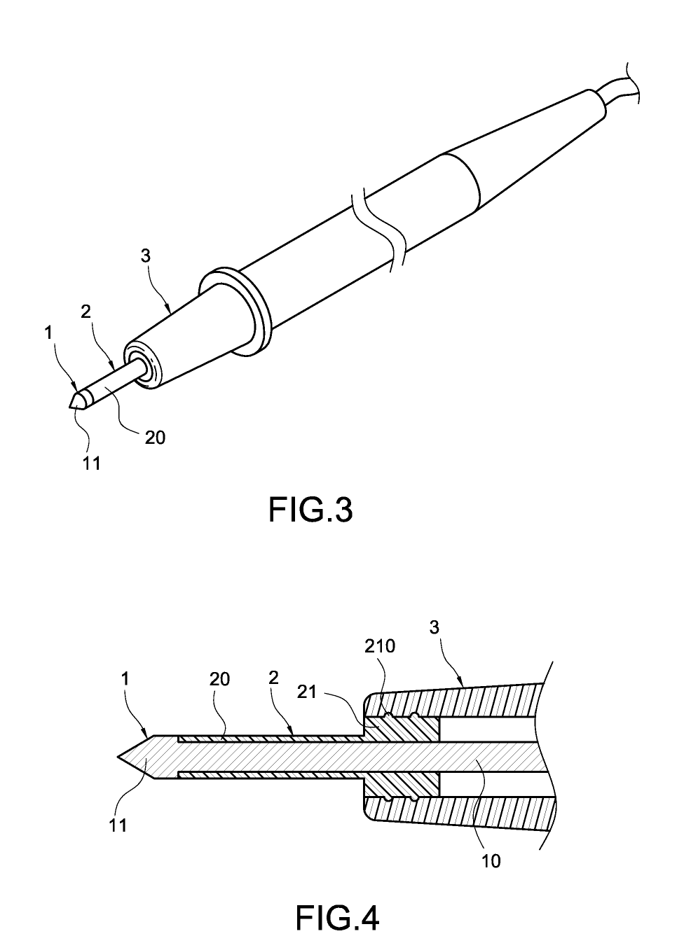

The coating element 2 is made of an insulating material and coated by an injection molding method, or formed onto the rod 10 of the probe tip body 1 by a manufacturing process using a high-temperature and wearing resisting material, and then coating and fixing the material by an injection molding process, wherein the insulating material can be plastic steel, ceramic, Teflon, polytetrafluoroethene (PTFE) or plastic containing fiber glass. The coating element 2 forms a continuing section 20 securely combined with the exterior of the rod 10, and a seat 21 is coupled to an end of the continuing section 20, and the seat 21 has a larger external diameter provided for installing the probe tip to the front end of the test probe 3 (as shown in FIGS. 3 and 4). In addition, at least one circular rib 210 is protruded from the exterior of the seat 21 for installing the probe tip to a front end of the test probe 3 securely and providing an axial resistance to prevent the probe tip from being separated from the test probe 3. In this preferred embodiment, the continuing section 20 has an external diameter exactly equal to the external diameter of the base of the probe head 11 (as shown in FIG. 4) for the situation of inserting the probe tip into a relatively narrower plug hole of a socket.

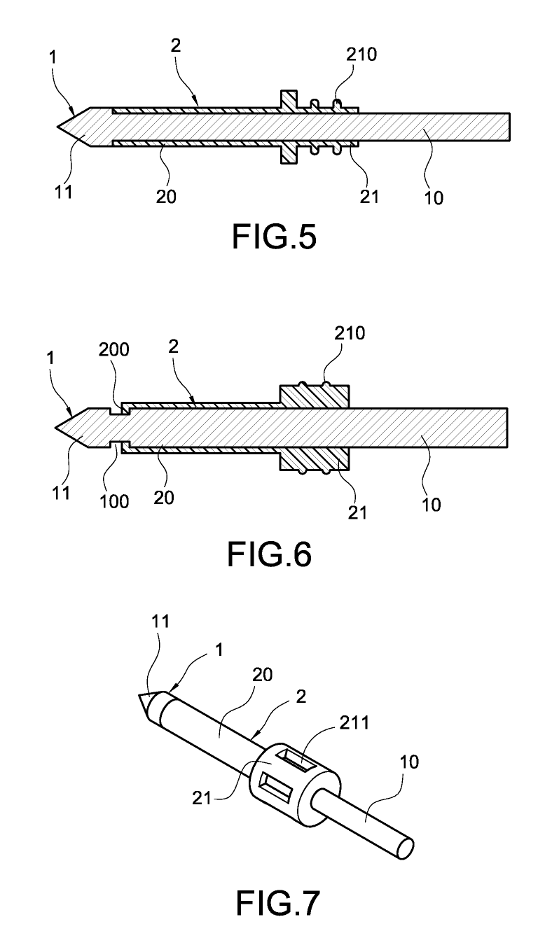

With reference to FIG. 5 for a cross-sectional view of a second preferred embodiment of the present invention, the seat 21 has an external diameter equal to the external diameter of the continuing section 20.

With reference to FIG. 6 for a cross-sectional view of a third preferred embodiment of the present invention, a circular relief notch 100 is concavely formed between the probe head 11 and the rod 10, and the front end of the continuing section 20 of the coating element 2 is extended to a flange 200 at a front edge of the rod 10 to increase the binding force between the continuing section 20 and the rod 10. In this preferred embodiment, the continuing section 20 has an external diameter greater than the external diameter of the base of the probe head 11.

With reference to FIG. 7 for a perspective view of a fourth preferred embodiment of the present invention, at least one inwardly concave embedding slot 211 is formed at the exterior of the seat 21 instead, such that when the test probe 3 is combined with the embedding slot 211, the plastic material is engaged with each embedding slot 211 to provide resistances in both axial and radial directions to prevent the probe tip from being separated from the test probe 3 easily.

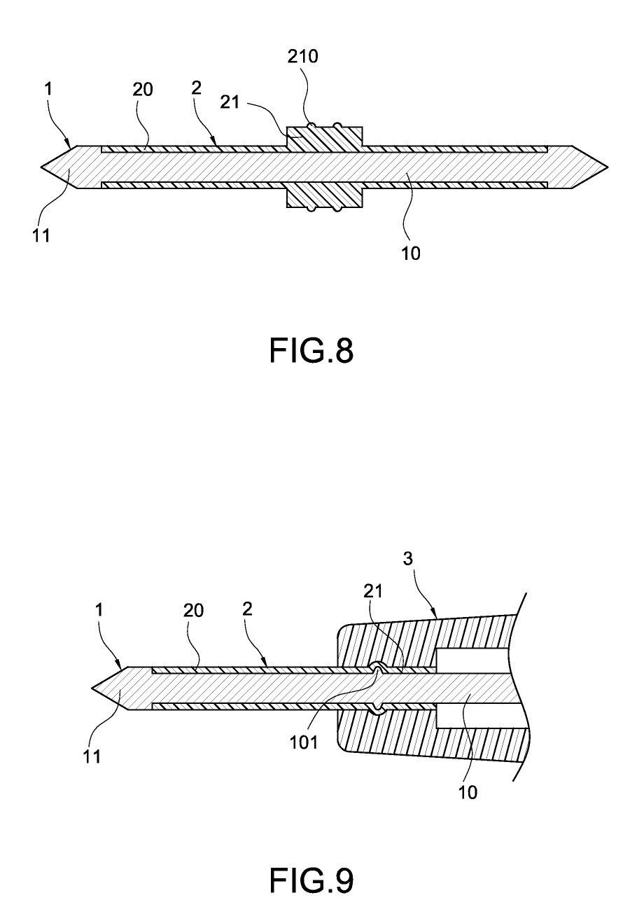

With reference to FIG. 8 for a cross-sectional view of a fifth preferred embodiment of the present invention, the probe tip body 1 further includes another probe head 11 extended from another end of the rod 10 for alternate uses. With reference to FIG. 9 for a partial cross-sectional view of a sixth preferred embodiment of the present invention, the seat 21 has an external diameter equal to the external diameter of the continuing section 20, and the rod 10 includes a bump 101 protruded from a position opposite to the seat 21, and the bump 101 props the seat 21 into a protruding shape for installing the probe tip to the front end of the test probe securely 3.

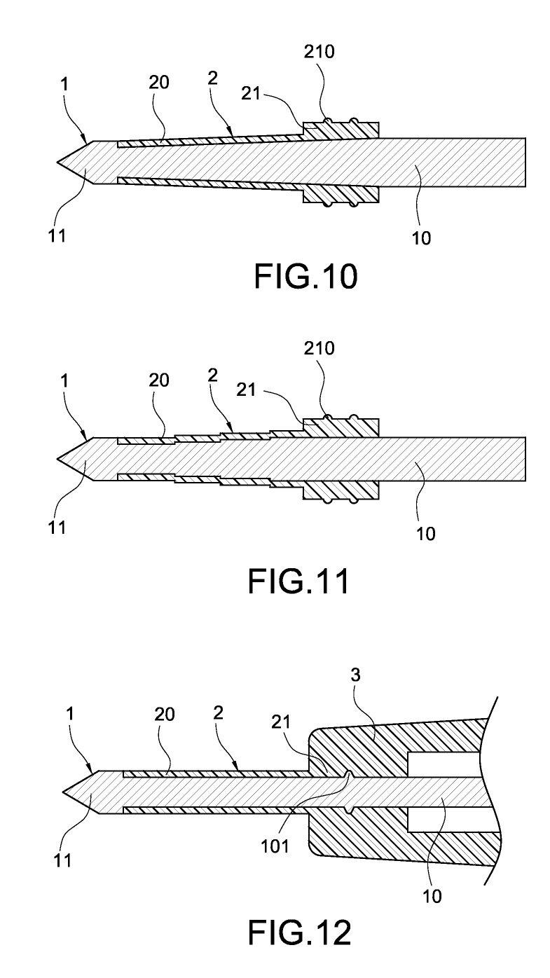

With reference to FIGS. 10 and 11 for cross-sectional views of seventh and eighth preferred embodiments of the present invention respectively, the rod 10 of the probe tip body 1 has a taper (as shown in FIG. 10), or the rod 10 of the probe tip body 1 is tapered from the seat 21 to the probe head 11 into a step shape to match the step shape of the continuing section 20 that is securely combined with the exterior of the rod 10 (as shown in FIG. 11), and the rod 10 has an external diameter of 2˜2.4 mm.

With reference to FIG. 12 for a partial cross-sectional view of a ninth preferred embodiment of the present invention, the coating element 2 can be integrally formed with the front end of the test probe 3. More specifically, the seat 21 of the coating element 2 is integrally combined into the front end of the test probe 3.

With the aforementioned assembly, the probe tip coating structure for test probes in accordance with the present invention can be achieved.

In summation of the description above, the present invention improves over the prior art and complies with the patent application requirements, and thus is duly filed for patent application.

While the invention has been described by means of specific embodiments, numerous modifications and variations could be made thereto by those skilled in the art without departing from the scope and spirit of the invention set forth in the claims.

What is claimed is:

1. A probe tip coating structure for test probes, comprising:
a probe tip body, having a rod, and a probe head integrally formed at a front end of the rod, and the rod having an external diameter not greater than the external diameter of the probe head; and
a coating element, coated on the rod, and forming a continuing section securely combined with the exterior of the rod, and having a seat coupled to an end of the continuing section and provided for assembling with the test probe.

2. The probe tip coating structure for test probes as recited to claim 1, wherein the probe head of the probe tip body is substantially cone-shaped.

3. The probe tip coating structure for test probes as recited to claim 1, wherein the rod of the probe tip body has an external diameter smaller than the external diameter of a base of the probe head.

4. The probe tip coating structure for test probes as recited to claim 1, wherein the rod of the probe tip body has an external diameter equal to the external diameter of a base of the probe head.

5. The probe tip coating structure for test probes as recited to claim 1, wherein the rod of the probe tip body has an external diameter less than 2.4 mm.

6. The probe tip coating structure for test probes as recited to claim 1, further comprising a circular relief notch concavely formed between the probe head of the probe tip body and the rod, and a front end of the continuing section of the coating element is further extended and coated onto a flange at a front edge of the rod.

7. The probe tip coating structure for test probes as recited to claim 1, wherein the rod of the probe tip body includes a bump protruded from a position opposite to the base, and provided for propping the base into a protruding form.

8. The probe tip coating structure for test probes as recited to claim 1, wherein the rod of the probe tip body has a taper.

9. The probe tip coating structure for test probes as recited to claim 8, wherein the rod has an external diameter of 2˜2.4 mm.

10. The probe tip coating structure for test probes as recited to claim 1, wherein the rod of the probe tip body is tapered from the base to the probe head into a step shape, such that the continuing section securely combined with the exterior of the rod is also in a corresponding step shape.

11. The probe tip coating structure for test probes as recited to claim 9, wherein the rod has an external diameter of 2˜2.4 mm.

12. The probe tip coating structure for test probes as recited to claim 1, wherein the probe tip body further includes another probe head extended from another end of the rod.

13. The probe tip coating structure for test probes as recited to claim 1, wherein the coating element is made of a material selected from the collection of plastic steel, ceramic, Teflon, and plastic containing fiber glass.

14. The probe tip coating structure for test probes as recited to claim 1, wherein the coating element is coated on the rod by an injection molding method or installed with a high-temperature and wearing resisting material and then fixed onto the rod by the injection molding method.

15. The probe tip coating structure for test probes as recited to claim 1, wherein the continuing section of the coating element has an external diameter equal to the external diameter of the base of the probe head.

16. The probe tip coating structure for test probes as recited to claim 1, wherein the continuing section of the coating element has an external diameter greater than the external diameter of the base of the probe head.

17. The probe tip coating structure for test probes as recited to claim 1, wherein the base of the coating element has an external diameter equal to the external diameter of the continuing section.

18. The probe tip coating structure for test probes as recited to claim 1, wherein the base of the coating element further includes at least one circular rib protruded from the exterior of the base.

19. The probe tip coating structure for test probes as recited to claim 1, wherein the base of the coating element further includes at least one inwardly concave embedding slot formed at the exterior of the base.

20. The probe tip coating structure for test probes as recited to claim 1, wherein the base of the coating element is integrally combined into a front end of the test probe.
